(19) United States
(12) Patent Application Publication
(10) Pub. No.: US 2011/0277806 A1
(43) Pub. Date: Nov. 17, 2011

(54) LOW PROFILE FLEXIBLE PHOTOVOLTAIC CELL MEMBRANE SYSTEM

(75) Inventor: Richard Gillenwater, Carlisle, PA (US)

(73) Assignee: Carlisle Intangible Company, Syracuse, NY (US)

(21) Appl. No.: 12/927,559

(22) Filed: Sep. 28, 2010

Related U.S. Application Data
(60) Provisional application No. 61/317,940, filed on Mar. 26, 2010.

(51) Int. Cl. H01L 31/042

(52) U.S. Cl. 136/244

(57) ABSTRACT

A low profile flexible photovoltaic cell system, which is particularly suitable for use on sloped surfaces such as hills, landfills, and the like, includes a plurality of photovoltaic cells adhered to a flexible membrane. The cells are aligned so that the electrical wiring for each cell is at an upper edge of the membrane as it would be located on a sloped surface. A flexible flap, preferably made out of the same flexible membrane, is bonded to the flexible membrane immediately above the top edges of the aligned photovoltaic cells. The flap extends downwardly and covers the electrical connections of the photovoltaic cells. The free end of the flap is, in turn, fixed to the membrane fastened to areas between adjacent photovoltaic cells using a hook and tile type fastener, or a strap, or other type of connector. This protects the electrical connections of the photovoltaic cells from the elements, in particular, water, snow and ice, but can be easily opened for inspection or repair.

### BACKGROUND OF THE INVENTION

There are a variety of types of solar panels and solar collectors. Some are relatively rigid panels. Others are flexible panels or sheets. These flexible photovoltaic cells have been attached to roof membranes. This is disclosed, for example, in Laaly et al. U.S. Pat. No. 4,860,509.

Generally, flexible photovoltaic systems attached to roof membranes have been used on flat roofs. However, these are now being used on sloped surfaces, and are particularly useful for covering landfills. The membrane prevents water from seeping into the top of the landfill and prevents landfill gases from escaping into the atmosphere. Further, the landfill, which is generally not suited for other uses, can be used to generate electricity.

Locating a photovoltaic system attached to a flexible membrane on a sloped surface is different from locating it on a generally flat roof surface. With a sloped surface, one must deal with significant water flow, as well as snow and ice, which flow down the surface. This applies forces which tend to separate the wiring or photovoltaic cells from the membrane.

The present wire trace systems that are used above the membrane carry the wiring at or above the membrane surface and are generally attached to the membrane material that is the waterproofing layer for a roof, landfill, or other applications. In some applications like landfills, the attachment to the membrane is the only option. The methods where the wire trace is attached to the membrane may not resist the forces of sliding ice or snow down the slope leading to an electrical failure and in some cases tearing open the membrane allowing water or snow entry into the structure. Another major weakness of these above membrane systems is they will not protect the up-slope adhesive edge or terminals of the PV module-laminate from the rain, ice, and snow.

An alternative to the above membrane installation is to bury the wiring in conduit under the membrane. This is a viable option but is costly and difficult to service. In landfill applications, this buried conduit has to handle the variable earth settling that occurs as these landfills age. This settling is generated by the decomposition and liquid runoff of the contents of the landfill and can generate great forces that can lead to conduit-wiring failure.

### SUMMARY OF THE INVENTION

Accordingly, it is an object of the present invention to provide a flexible photovoltaic cell membrane system wherein the wiring between the photovoltaic cells remains above the surface of the membrane and is protected from the elements, in particular water, snow and ice.

More particularly, the present invention is premised on the realization that a photovoltaic system for use on a sloped surface can be prepared wherein the photovoltaic cells are bonded to the membrane so that the electrical connections of each of the cells are located at an upper edge of the membrane, as the membrane would be positioned on a hillside. A narrow flap of membrane material is bonded to the top upper edge of the membrane immediately above the top of the photovoltaic cells. The flap extends over the top of the cells so that it covers all of the electrical wiring. In turn, the bottom edge of the flap can be fastened to the membrane using a hook and pile type fastener, or other type of fastener, located in the area between adjoining photovoltaic cells. The fastener holds the flap over the electrical components. Since the upper edge of the flap is tightly bonded to the membrane, snow and ice traveling down the side of the hill will simply go up and over the flap and the electrical connections.

To further reduce the profile and to protect the wiring, the wiring can be encased in a low profile protective member or raceway. The raceway can be adhered to the membrane beneath the flap. This not only reduces the height or profile of this area, it also protects the wiring.

The objects and advantages of the present invention will be further appreciated in light of the following detailed description and drawings in which:

### BRIEF DESCRIPTION OF THE DRAWINGS

FIG. 1 is a perspective view of the present invention;

FIG. 2 is an enlarged portion of FIG. 1 broken away, showing electrical connections in phantom;

FIG. 3 is an enlarged portion broken away of the area delineated by Box 3 of FIG. 2;

FIG. 4 is a cross-sectional view taken at lines 4-4 of FIG. 1;

FIG. 5 is a cross-sectional view similar to FIG. 4 of an alternate embodiment;

FIG. 6 is a perspective view broken away of an alternate embodiment of the present invention;

FIG. 7 is an enlarged view of the boxed area 7 of FIG. 6 with the flap opened; and

FIG. 8 is a cross sectional view taken at line 8-8 of FIG. 7.

### DETAILED DESCRIPTION

According to the present invention, a flexible photovoltaic cell system 10 is located over a sloped surface. Generally, a sloped surface can have a slope of 0.25:12 or greater. This can be a sloped roof or a sloped landfill area 12. The drawings show a landfill area 12. (However the numeral 12 could also designate a sloped roof surface.) The landfill 12 will typically be sloped, having an uphill side 14 and a downhill side 16. The general slope of the landfill is shown by arrow 18. Flexible photovoltaic system 10 includes a flexible polymeric membrane 22, and as shown, a first array 24 and a second array 26 of individual flexible photovoltaic cells 28.

Each of the individual cells 28 is fixed to the membrane by well-known methods. Typically, the cells are either adhered or heat-welded to the membrane 22.

The membrane can be any membrane suitable for exterior use, such as PVC, EPDM, TPO, HDPE, and LLDPE, and the like. One membrane particularly suitable for use in the present invention is a fiber-reinforced TPO membrane. The fiber reinforcement allows the membrane to withstand stresses encountered during movement of the landfill, which may occur during compaction of the soil and the like.

The individual cells 28 are located side by side on the membrane 22 with spacing 38 between the cells. Each cell 28 includes a top 32 and a bottom 34. The top 32 includes the electrical connections, including the positive and negative leads 42 and 44, which in turn lead to wires 48 and 50, in turn leading to connectors 54 and 56. It should be noted that the drawing shows the individual cells wired in series, with the individual arrays wired in parallel; however, this is simply a matter of choice, and the cells can be connected either in parallel or in series as desired.

The top portions 32 of the arrays of the cell 28 are covered with an elongated, narrow, continuous, flap 60. The flap 60, which can be formed from the same material as the membrane 22 or a different material such as metal or rubber coated metal, is bonded along a top edge 62 to the membrane 22. The flap extends from above the array of cells over the electrical connections to a point so that the free edge 64 of the flap 60 lies downhill from the electrical connections.

If the flap is a more rigid material, which will not move under windy conditions, it does not need to be further connected to the membrane 22. However, if the flap 60 is, for example, a flap of a polymeric material, such as for example the same material from which the membrane is formed, it may be desirable to fix the bottom edge 64 to the membrane 22. Accordingly, as shown in FIG. 4, the flap includes a first complementary fastener 66 and the membrane includes a second complementary fastener 68, which is located in the spacing 38 between the individual cells 28. The first complementary fastener 66 can be a hook portion, bonded with an adhesive 72 to bottom edge 64 of flap 60. In turn, the membrane 22 includes a pile portion as the second complementary fastener 68 bonded to the membrane 22 with an adhesive 76. Thus, the fastener members 66 and 68 as shown in FIG. 4 would comprise a hook and pile fastener.

An alternate embodiment is shown in FIG. 5, in which a strap 78 is heat-welded to a top surface 80 of flap 60 and bonded to the membrane 22 in the spacing area with an adhesive 82. Other complementary fastening methods can be used, such as straps with buckles, snap fasteners, and the like.

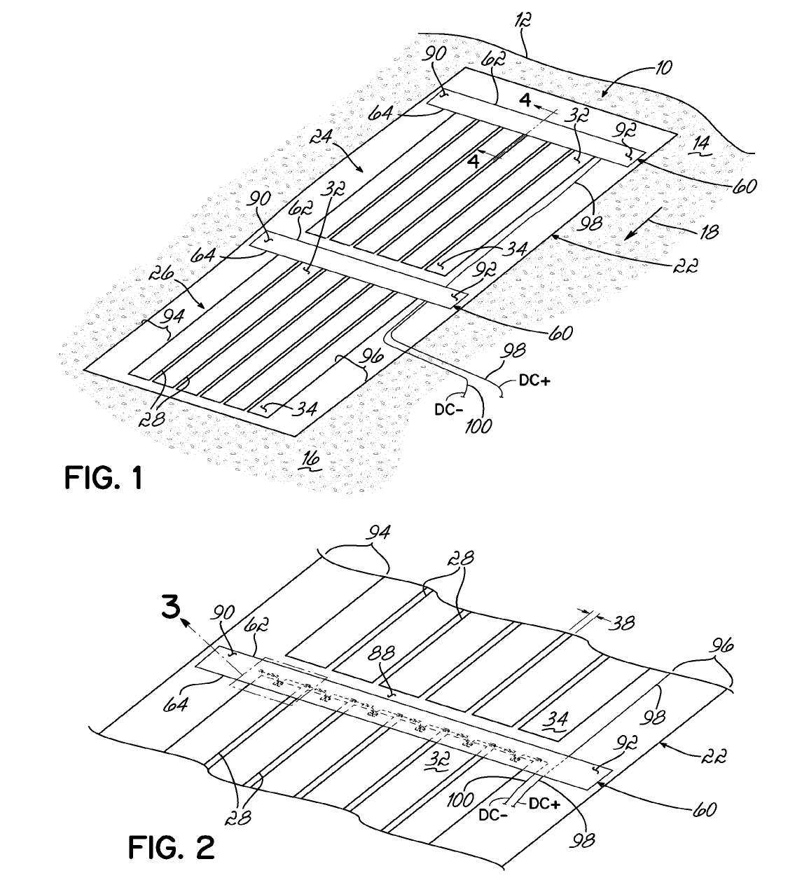

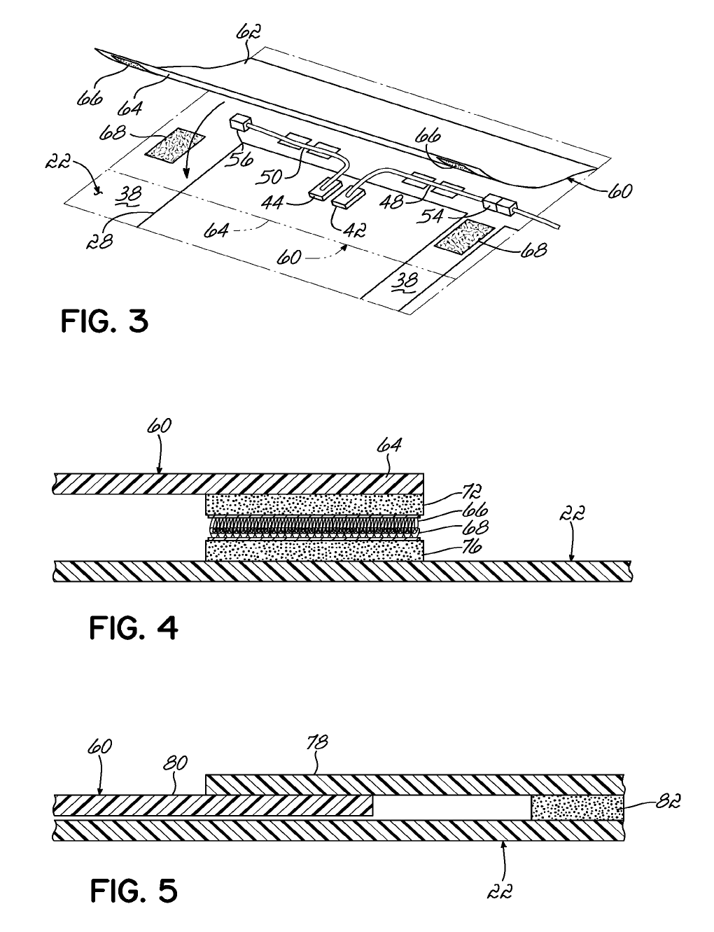

As shown more particularly in FIG. 1, the upper array 24 is separated from the bottom array 26 by a slight spacing 88. Both the top and bottom arrays incorporate a flap 60, with each flap 60 extending completely across the top of each array, with the side portions 90 and 92, which extend slightly beyond the array, leaving 6 inch edge portions 94 and 96 of the membrane 22 along either side to allow adjacent membranes to be adhered side by side together if desired (although no such additional membranes are shown in the drawings.)

The membrane 22 is held to the landfill by, for example, burying the edges of the membrane in trenches in the landfill. Other mechanical fastening mechanisms can also be used. A typical system is disclosed, for example, in published PCT application WO 2009/105483, the disclosure of which is incorporated herein by reference. The leads 98 and 100 can lead to adjacent photovoltaic systems or can be directed to batteries or converters as desired.

Preferably, the cover 10 will be manufactured offsite by adhering the cells 28 in the arrays 24 or 26 to the membrane 22. The flaps 60 are then heat-welded or adhered to the membrane 22 covering the electrical connections as shown in FIG. 1. This entire system is rolled and transported to a landfill where it can be installed by simply unrolling the membrane and installing it using well-known techniques.

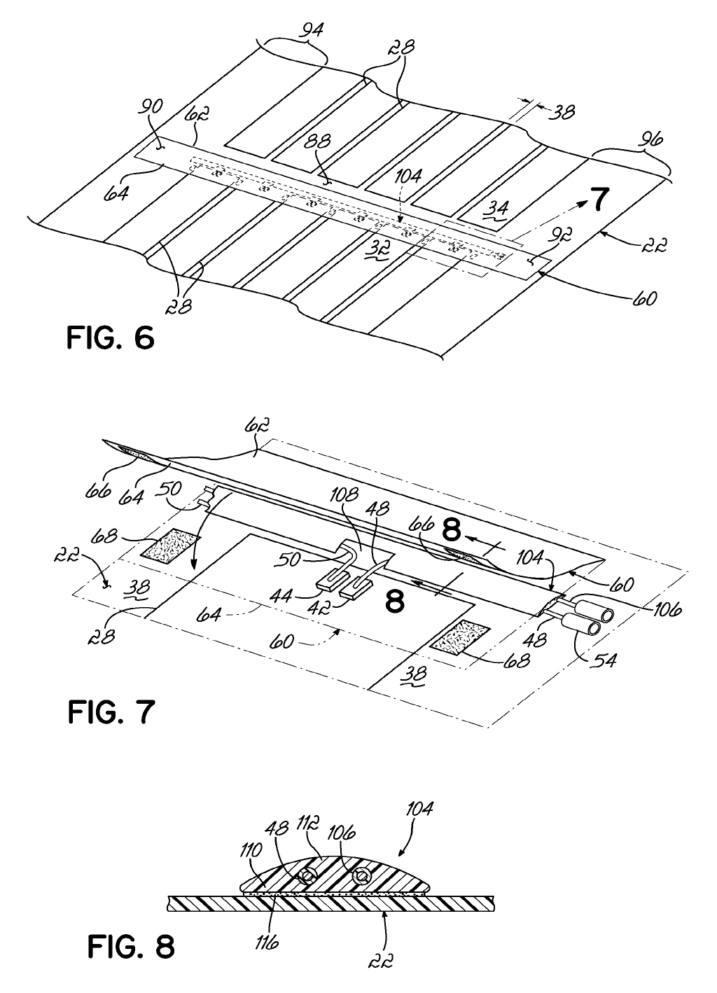

FIGS. 6, 7, and 8 show an alternate embodiment of the present invention in which the wiring and connectors are held within a protective member or raceway 104. As shown, the wires 48 and 50 run through raceway 104. The connectors 42 and 44 extend from a cut out portion 108 of the raceway. There is also a connecting wire 106 that runs through the length of the raceway which simply connects to the final lead of the final cell.

The raceway 104 has a flat bottom portion 110 and an arcuate upper portion 112. The flat bottom portion 110 is preferably adhered to the membrane surface. Thus, at the top of each cell 28 there will be a raceway 104 which contains all the wiring. The connectors then will extend beyond the raceway 104 and connect to the wiring from the adjacent cell.

The raceway 104 acts to maintain a low profile keeping the wiring close to the surface of the membrane 22. The arcuate top surface, in turn, has no sharp edges which could penetrate the flap 60 if someone were to step on the raceway. Further, the raceway protects the wiring.

Preferably, the raceway is formed from a somewhat rigid material such as a solid rubber or other polymer. Its ability to flex under pressure will prevent it from cracking. Therefore, it is preferable to make it from a material such as rubber.

The raceway also can be held either permanently fixed to the membrane using an adhesive or heat welding, or, alternately can be removably fixed to the membrane, using, for example, a hook and pile type fastening system.

The present invention provides many advantages. The flap 60 covering the electrical connections has a low profile, and can be less than an inch in height. Thus it will not significantly impede the flow of water, ice, and snow flowing down the side of the landfill. Preferably, the flap will have an upper low-friction surface. Typically, polymeric membranes can be formed with a smooth surface, which allows material to flow down more easily. The flap protects the upslope edge of the laminate, and protects the terminals by deflecting the rain, ice, and snow. This reduces the forces which act to separate the cover from the landfill. With the embodiments shown in FIG. 4, or other embodiments using releasable fastening systems, the wiring can be easily accessed for inspection and repair. The flexibility of the cover allows the entire photovoltaic cover 10 to be manufactured offsite and rolled up on a core for storage and shipping. Finally, it allows most of the wiring to be finished and connected offsite, again reducing installation costs.

This has been a description of the present invention along with the preferred method of practicing the present invention. However, the invention itself should only be defined by the appended claims, WHEREIN I CLAIM:

What is claimed is:

1. A flexible photovoltaic cell system comprising
a supporting flexible membrane;
a first plurality of flexible photovoltaic cells each having a top edge and a bottom edge and electrical connections at said top edges;
said plurality of cells fixed to said flexible membrane with said top edges of said cells aligned along a top portion of said membrane and wherein said plurality of cells are spaced from each other leaving exposed strips of said membrane between adjacent cells;
a narrow flap having a top edge bonded to said top portion of said flexible membrane above said top edges of said cells substantially the width of said membrane and extended from said top edge downwardly covering said electrical connections.

2. The photovoltaic cell system claimed in claim 1 further comprising fasteners located in said exposed strips and complementary fastener members fixed to a bottom surface of said flap.

3. The photovoltaic cell system claimed in claim 2 wherein said fastener member and complementary fastener members are hook and pile fasteners.

4. The photovoltaic cell system claimed in claim 2 wherein said fastener members and said complementary fastener members are straps and buckles.

5. The photovoltaic cell system claimed in claim 1 further comprising a second plurality of flexible photovoltaic cells fixed to said membrane below said first plurality of photovoltaic cells wherein each of said second plurality of flexible photovoltaic cells has a top edge adjacent bottom edges of first plurality of flexible photovoltaic and electrical connections along said top edges;
a second flap having a top edge bonded to said flexible membrane in an area between said first and second plurality of flexible photovoltaic cells said second flap extending downwardly covering said top of said second plurality of photovoltaic cells and extended from said top edge downwardly covering electrical connections of said second plurality of flexible photovoltaic cells.

6. The flexible photovoltaic system claimed in claim 1 wherein said cell system is mounted on a hill with the upper edge of said membrane higher than the bottom of said membrane whereby said flap prevents water flowing down said hill from contacting said electrical connectors.

7. The photovoltaic cell system claimed in claim 1 further comprising first and second wires extending from said electrical connector said wires encased in a protective member.

8. The photovoltaic cell system claimed in claim 7 wherein said protective member comprises a low profile solid member having a flat bottom and an arcuate top.

9. The photovoltaic cell system claimed in claim 8 wherein said solid member is a polymer.

10. The photovoltaic cell system claimed in claim 8 wherein said bottom surface if adhered to said membrane.

11. The photovoltaic cell system claimed in claim 1 wherein said cell system is mounted on a sloped roof surface.
